(19) United States
(12) Patent Application Publication
(10) Pub. No.: US 2025/0248292 A1
(43) Pub. Date: Jul. 31, 2025

(54) DISPLAY DEVICE

(71) Applicant: LG Display Co., Ltd., Seoul (KR)

(72) Inventors: Sangmin WOO, Paju-si (KR); Jisoon OH, Goyang-si (KR); Hyeonggwang AN, Incheon (KR); Jaewoo LEE, Goyang-si (KR); Shinsuk LEE, Gimpo-si (KR); Namseok LEE, Paju-si (KR)

(21) Appl. No.: 18/798,381

(22) Filed: Aug. 8, 2024

(30) Foreign Application Priority Data
Jan. 31, 2024 (KR) 10-2024-0015205

(51) Int. Cl. H10K 59/90; H05K 1/02; H05K 1/14; H10K 59/131

(52) U.S. Cl. CPC H10K 59/90; H05K 1/0224; H05K 1/147; H10K 59/131; H05K 2201/10128

(57) ABSTRACT

A display device includes a display panel with a display area including a plurality of pixels and a pair of opposing sides. A first printed circuit board is disposed on one of the pair of opposing sides and a second printed circuit board is disposed on the other of the pair of opposing sides of the display panel. A ground flexible printed circuit board includes a pair of opposing sides with one of the pair of opposing sides of the ground flexible printed circuit board electrically connected to the display panel, while the other of the pair of opposing sides of the ground flexible printed circuit board is connected to the second printed circuit board. The ground flexible printed circuit board is connected to a ground to discharge accumulated charges and maintain impedance matching.

### CROSS-REFERENCE TO RELATED APPLICATION

This application claims priority from Korean Patent Application No. 10-2024-0015205 filed on Jan. 31, 2024 in the Korean Intellectual Property Office, and all the benefits accruing therefrom under 35 U.S.C. 119, the entire contents of which are incorporated herein by reference.

### BACKGROUND

### Technical Field

The present disclosure relates to a display device, and more specifically, to a foldable display device.

### Description of the Related Art

Display devices are applied to various electronic devices such as TVs, mobile phones, laptops, and tablets. To this end, research is continuing to develop display devices that are smaller, lighter, and have lower power consumption.

Examples of display devices include liquid crystal display apparatus (LCD), field emission display apparatus (FED), and organic light-emitting display apparatus (OLED).

Recently, research on thin and light display panels has been actively conducted. Research on a variable display device such as a flexible display device whose display panel may be bent into a curved state or return to a flat state, or a foldable display device in which the display panel is able to be folded or unfolded for application to household goods such as furniture as well as electronic products such as wearable devices, televisions, monitors, smartphones, tablet PCs, and laptops is continuing.

There are a number of challenges and deficiencies with relatively thin foldable or flexible display devices. For example, as the thickness of the display decreases, noise in the display increases. Further, for larger foldable displays, there is an increase in the signal transmission path that can create challenges with durability of the display and quality of image displayed on the display. Accordingly, it would be advantageous to have a display device that overcomes the deficiencies and disadvantages of prior solutions.

### BRIEF SUMMARY

In order to repeatedly perform bending, folding, or unfolding operations in the flexible display device, a thickness of a display panel is becoming smaller. However, as the thickness of the display panel becomes smaller, influence of noise generated when the display device operates increases. Furthermore, as a size of an electronic product including a bendable or foldable display panel increases, a size of the display panel increases and thus a signal transmission path length increases.

According to one or more embodiments of the present disclosure, a display device includes a ground flexible printed circuit board that may stably discharge charges accumulated inside a bendable or foldable display panel to the outside.

According to one or more embodiments of the present disclosure, a display device includes a ground flexible printed circuit board that may maintain impedance matching between one side of a bendable or foldable display panel and the other side thereof opposite to the one side when a size of the bendable or foldable display panel increases.

According to one or more embodiments of the present disclosure, a display device is provided in which the ground flexible printed circuit board is connected to the printed circuit board via a connector structure to keep resistance values at both opposing sides of the display panel to be equal to each other.

A display device according to an embodiment of the present disclosure may include a display panel including a display area including a plurality of pixels, wherein the display panel has both opposing sides; a first printed circuit board disposed on one of the both opposing sides; a second printed circuit board disposed on the other of the both opposing sides; and a ground flexible printed circuit board having both opposing sides, wherein one of the both opposing sides of the ground flexible printed circuit board is electrically connected to the display panel, while the other of the both opposing sides of the ground flexible printed circuit board is connected to the second printed circuit board, wherein the ground flexible printed circuit board is connected to a ground.

According to an embodiment of the present disclosure, even when the thickness of the display panel becomes smaller, the influence of noise generated when the display device operates on video or image quality may be reduced, thereby slimming the display panel to implement a lightweight display panel and thus to reduce a weight of an electronic product.

Furthermore, according to an embodiment of the present disclosure, the ground flexible printed circuit board may be connected to the printed circuit board via the connector structure such that the static charges may be stably discharged to the outside. Accordingly, when the size of the display panel increases, the contrast ratio of the screen emitted from the display area may be improved.

Furthermore, according to an embodiment of the present disclosure, the ground flexible printed circuit board may include the resistance patterns. Thus, when the size of the display panel increases, the resistance of one side and the resistance of the other side of the display panel may be kept to be equal to each other. Accordingly, the signal strength of the active pen may be increased while the noise size is reduced. As a result, the display device that may operate with low power and thus reduce power consumption may be realized.

Embodiments of the present disclosure are not limited to the embodiments mentioned above, and other embodiments not mentioned will be clearly understood by those skilled in the art from the following description with reference to the accompanying drawings. Further, it will be easily understood that the embodiments and advantages according to the present disclosure may be realized using means shown in the claims or combinations thereof.

### BRIEF DESCRIPTION OF THE SEVERAL VIEWS OF THE DRAWINGS

FIG. 1 and FIG. 2 are schematic perspective views of a display device according to an embodiment of the present disclosure in an unfolded and a folded state, respectively.

FIG. 3 is a cross-sectional view of the display device in FIG. 1 along line 3-3 in FIG. 1.

FIG. 4 is a front plan view showing a portion of a display panel according to an embodiment of the present disclosure.

FIG. 5 is a rear plan view of the display panel in FIG. 4.

FIG. 6 is a cross-sectional view of the display panel of FIG. 4 along line 6-6 in FIG. 4.

FIG. 7 is a schematic diagram showing signal input of an active pen on a display device according to an embodiment of the present disclosure.

FIG. 8 is a diagram showing a ground flexible printed circuit board according to an embodiment of the present disclosure.

FIG. 9 is a cross-sectional view of the display panel of FIG. 5 along line 9-9 in FIG. 5.

FIG. 10 is a front plan view showing a portion of a display panel according to an embodiment of the present disclosure.

FIG. 11 is a rear plan view of the display panel in FIG. 10.

FIG. 12 and FIG. 13 are enlarged views of area 12 of the display panel in FIG. 10.

FIGS. 14 to 16 are diagrams showing a ground flexible printed circuit board according to an embodiment of the present disclosure.

FIG. 17 is a diagram showing impedance matching based on a connection structure of the ground flexible printed circuit board in accordance with the embodiments of the present disclosure.

FIG. 18 and FIG. 19 are graphs showing a noise level and a signal level of an active pen according to embodiments of the present disclosure.

### DETAILED DESCRIPTION

Advantages and features of the present disclosure, and a method of achieving the advantages and features will become apparent with reference to embodiments described later in detail together with the accompanying drawings. However, the present disclosure is not limited to the embodiments as disclosed under, but may be embodied in various different forms. Thus, these embodiments are set forth only to make the present disclosure complete, and to completely inform the scope of the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality, unless otherwise noted. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure.

A shape, a size, a ratio, an angle, a number, etc., disclosed in the drawings for illustrating embodiments of the present disclosure are illustrative, and the present disclosure is not limited thereto.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise,” “comprising,” “include,” and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

It will be understood that when an element or layer is referred to as being “connected to,” or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like is disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after,” “subsequent to,” “before,” etc., another event may occur therebetween unless “directly after,” “directly subsequent” or “directly before” is not indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first,” “second,” “third,” and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described under could be termed a second element, component, region, layer or section, without departing from the spirit and scope of the present disclosure.

Spatially relative terms, such as “beneath,” “below,” “lower,” “under,” “above,” “upper,” and the like, may be used herein for ease of explanation to describe one element or feature's relationship to another element or feature as illustrated in the figures. It will be understood that the spatially relative terms are intended to encompass different orientations of the device in use or in operation, in addition to the orientation depicted in the figures. For example, when the device in the drawings may be turned over, elements described as “below” or “beneath” or “under” other elements or features would then be oriented “above” the other elements or features. Thus, the example terms “below” and “under” may encompass both an orientation of above and below. The device may be otherwise oriented for example, rotated 90 degrees or at other orientations, and the spatially relative descriptors used herein should be interpreted accordingly.

The features of the various embodiments of the present disclosure may be partially or entirely combined with each other, and may be technically associated with each other or operate with each other. The embodiments may be embodied independently of each other and may be embodied together in an association relationship.

In interpreting a numerical value, the value is interpreted as including an error range unless there is no separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects,” and the like should not be construed such that any aspect or design as described is superior to or advantageous over other aspects or designs.

Further, the term ‘or’ means ‘inclusive or’ rather than ‘exclusive or.’ That is, unless otherwise stated or clear from the context, the expression that ‘x uses a or b’ means any one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for illustrating embodiments.

Further, in a specific case, a term may be arbitrarily selected by the applicant, and in this case, the detailed meaning thereof will be described in a corresponding description section. Therefore, the terms used in the description below should be understood based on not simply the name of the terms, but the meaning of the terms and the contents throughout the Detailed Descriptions.

In description of flow of a signal, for example, when a signal is delivered from a node A to a node B, this may include a case where the signal is transferred from the node A to the node B via another node unless a phrase ‘immediately transferred’ or ‘directly transferred’ is used.

Hereinafter, a display device according to each of embodiments of the present disclosure will be described with reference to the attached drawings.

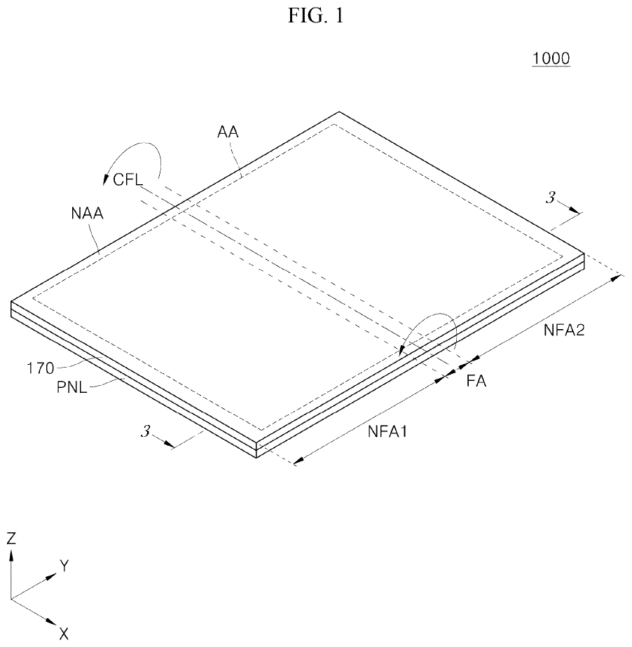

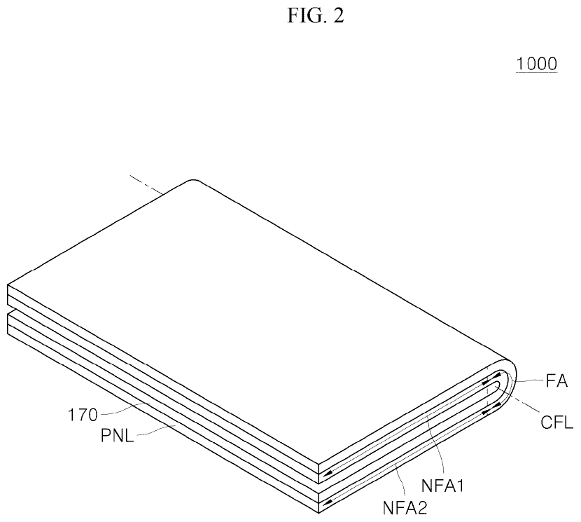

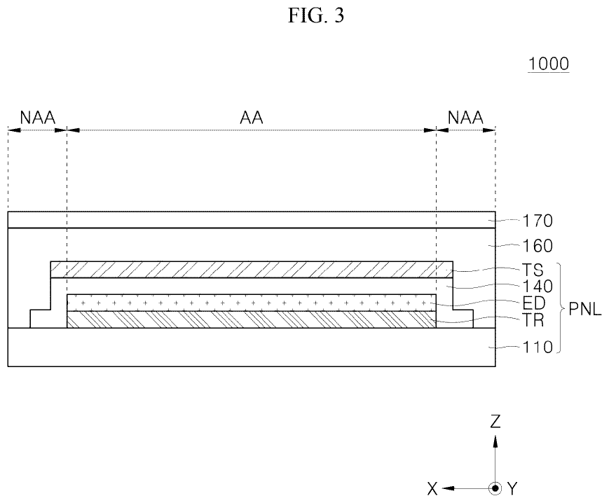

FIG. 1 and FIG. 2 are schematic perspective views of a display device according to an embodiment of the present disclosure. FIG. 3 is a cross-sectional view at one side of the display device in FIG. 1 along line 3-3 in FIG. 1. FIG. 1 shows the display device in an unfolded state, and FIG. 2 shows the display device in FIG. 1 in a folded state.

Referring to FIGS. 1 to 3, a display device 1000 according to an embodiment of the present disclosure may include a display panel PNL having a display area AA and a non-display area NAA located outside the display area AA, and a cover substrate 170.

In a plan view, the display device 1000 may have a rectangular shape with a short side extending in a first direction and a long side extending in a second direction. Alternatively, the display device 1000 may have a square shape with each corner having a rounded shape. However, embodiments of the present disclosure are not limited thereto. The first direction may be, for example, a X axis direction or a row direction of the display device, and the second direction may be, for example, a Y axis direction or a column direction of the display device. However, embodiments of the present disclosure are not limited thereto

The display area AA may display an image or video emitted from the display panel PNL and provide the same to the user. The non-display area NAA is an area where the image or video is not displayed, and one or more drivers may be disposed in the non-display area NAA to drive the display area AA. For example, the one or more drivers may include, but are not limited to, a gate driver, a data driver, a touch driver, or a timing controller.

The display device 1000 may include a folding area FA and a plurality of non-folding areas NFA1 and NFA2. The plurality of non-folding areas NFA1 and NFA2 may include a first non-folding area NFA1 and a second non-folding area NFA2. The folding area FA may be disposed between the first non-folding area NFA1 and the second non-folding area NFA2.

The folding area FA of the display panel PLN may be bent along a central folding line or axis CFL parallel to the first direction (e.g., X-axis direction). The folding area FA may have a predetermined radius of curvature, which may be, in a non-limiting example, 4 millimeters or less. The display device 1000 may be folded until the display area AA of the first non-folding area NFA1 and the display area AA of the second non-folding area NFA2 face inward each other and touch each other. In this case, the display area AA may not be exposed to an outside. In one example, in a state in which the display panel PNL is unfolded, the first non-folding area NFA1 may be selectively folded so that an angle between the first non-folding area NFA1 and the second non-folding area NFA2 becomes a predetermined angle. Alternatively, in a state in which the display panel PNL is unfolded, the second non-folding area NFA2 may be selectively folded so that an angle between the first non-folding area NFA1 and the second non-folding area NFA2 becomes a predetermined angle. In other words, in some embodiments, each of the non-folding areas NFA1, NFA2 can be selectively and independently bent or folded at a selected angle relative to the other non-folding area NFA1, NFA2. For example, the first non-folding area NFA1 may be folded and held in position at an angle of 30 degrees or any other selected angle between 0 degrees (i.e., the flat, unfolded state shown in FIG. 1) and approximately 180 degrees in which the non-folding areas NFA1, NFA2 contact each other.

Referring to FIG. 1 and FIG. 3 together, the display device 1000 may include a structure in which the display panel PNL and the cover substrate 170 are bonded to each other. The display panel PNL may include, in generally successive order bottom to top in a “Z” direction, a base substrate 110, a transistor area TR (or transistor TR), a light-emitting element area ED (or light-emitting element ED or light-emitting layer ED), an encapsulation area 140 (or encapsulation layer 140), and a touch sensing area TS (or touch sensing layer TS). The display panel PNL and the cover substrate 170 may be sealed with a sealing area 160 (or sealing layer 160 or adhesive 160).

The base substrate 110 of the display panel PNL may include transparent plastic or glass. The cover substrate 170 may include a transparent plastic film, glass, or an encapsulation film. The cover substrate 170 may be referred to as a cover window, a window cover, or a cover glass that covers the display panel PNL.

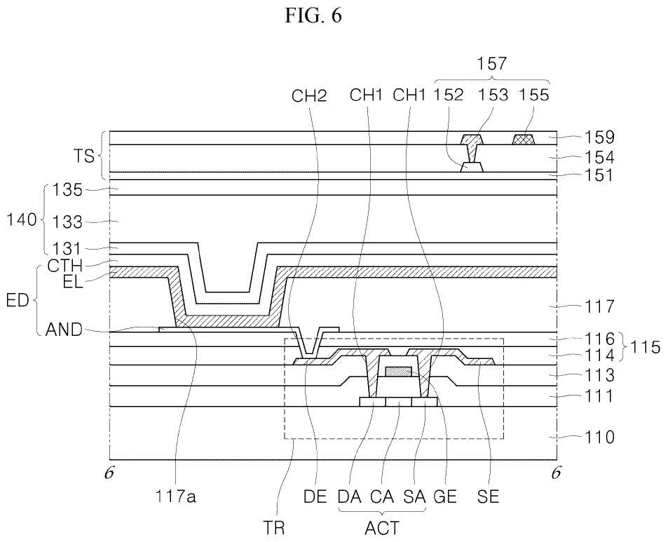

The transistor area TR may be disposed on the base substrate 110. The transistor area TR may include a plurality of thin film transistors, a plurality of scan lines, and a plurality of data lines. A detailed description of the transistor area TR will be made later with reference to FIG. 6.

The light-emitting element area ED may be disposed on the transistor area TR. The light-emitting element area ED may have a plurality of light-emitting elements, each having a stack structure of a first electrode, a light-emitting layer, and a second electrode. For example, the light-emitting layer may be an organic light-emitting layer including an organic material. Embodiments of the present disclosure are not limited thereto. A driving current may be applied to the first and second electrodes located on top of and under the light-emitting layer, so that the light-emitting layer may emit light. A detailed description of the light-emitting element area ED will be made with reference to FIG. 6 below.

The encapsulation area 140 may be disposed on the light-emitting element area ED. In an embodiment, the light-emitting layer contains organic material and is therefore vulnerable to oxygen and moisture. Accordingly, the encapsulation area 140 may seal the light-emitting layer containing the organic material to prevent oxygen or moisture from invading therein. The encapsulation area 140 may include an inorganic insulating layer or an organic insulating layer having a multi-layer structure. A detailed description of the encapsulation area 140 will be made later with reference to FIG. 6.

The touch sensing area TS may be disposed on the encapsulation area 140. The touch sensing area TS may include a plurality of touch electrodes for detecting a user's touch, bridge electrodes for electrically connecting adjacent touch electrodes to each other, and a protective layer to protect the touch electrodes. A detailed description of the touch sensing area TS will be made later with reference to FIG. 6.

The sealing area 160 may be disposed between the base substrate 110 and the cover substrate 170 of the display panel PNL while covering the touch sensing area TS. The sealing area 160 may further include an adhesive or adhesive layer that improves a sealing function and an adhesive force between the base substrate 110 and the cover substrate 170. The sealing area 160 may further include a polarizing layer disposed between the touch sensing area TS and the cover substrate 170, with the polarizing layer being above or below the adhesive layer.

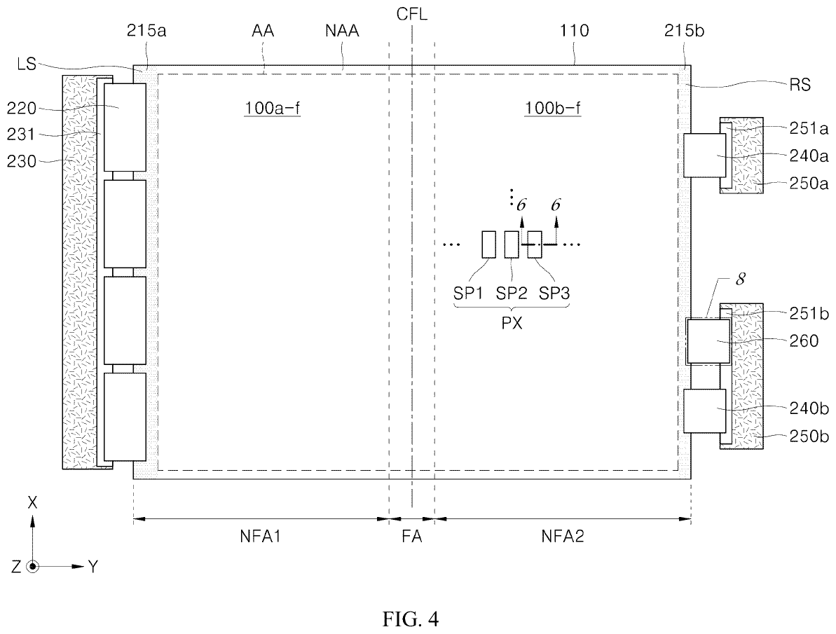

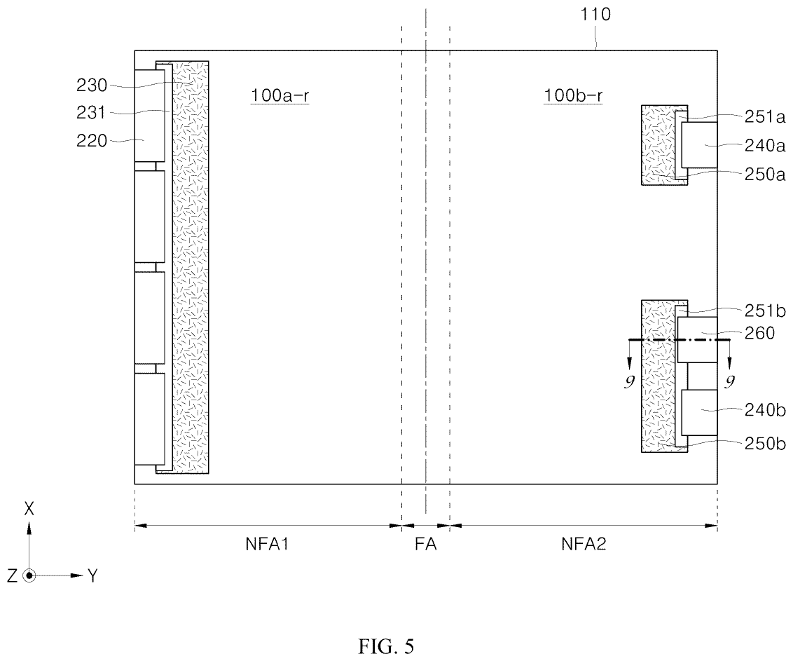

FIG. 4 is a front plan view showing a portion of the display panel according to an embodiment of the present disclosure. FIG. 5 is a rear plan view showing the display panel in FIG. 4. FIG. 6 is a cross-sectional view along a line 6-6 in FIG. 4. In FIG. 4, for convenience of illustration, the touch sensing area TS is excluded. In FIG. 5, for convenience of illustration, a plurality of printed circuit boards illustrated in FIG. 4 are shown being bent and attached to the base substrate.

Referring to FIG. 4 and FIG. 5, the display panel PNL of the display device may include a display area AA and a non-display area NAA located outside the display area AA. The display area AA may have a first display area 100a-f located at a left side around the center folding line CFL and a second display area 100b-f located at a right side around the center folding line CFL. However, the present disclosure is not limited thereto. For example, the left side may be converted to one side in the column direction, and the right side may be converted to the other side in the column direction, or vice versa. Different images or videos may be displayed in the first display area 100a-f and the second display area 100b-f. Embodiments of the present disclosure are not limited thereto. For example, the same video or image may be displayed in the first display area 100a-f and the second display area 100b-f.

In the display area AA, a plurality of pixels PX may be arranged, each pixel including a plurality of sub-pixels SP1, SP2, and SP3. Videos or images may be displayed in the display area AA through the plurality of pixels PX. A plurality of data lines and a plurality of scan lines may be disposed in the display area AA. Each of the plurality of data lines may extend to intersect each of the plurality of scan lines. One sub-pixel may be defined by one data line and one scan line that intersect each other.

The plurality of sub-pixels SP1, SP2, and SP3 may be arranged in the display area AA in a matrix manner (M*N), where M and N are natural numbers. The plurality of sub-pixels SP1, SP2, and SP3 may include a first sub-pixel SP1, a second sub-pixel SP2, and a third sub-pixel SP3. A corresponding light-emitting element may be disposed in each of the first sub-pixel SP1, the second sub-pixel SP2, and the third sub-pixel SP3. The first sub-pixel SP1, the second sub-pixel SP2, and the third sub-pixel SP3 may emit light of different colors. For example, the first sub-pixel SP1, the second sub-pixel SP2, and the third sub-pixel SP3 may emit light of red, green, and blue colors, respectively. However, embodiments of the present disclosure are not limited thereto.

The driver may be disposed in the non-display area NAA surrounding the display area AA. The driver may be located in the non-display area NAA and on at least one side of the base substrate 110. The driver may include a gate driver, a data driver, or a timing controller. Furthermore, the driver may include a power wiring that supplies power voltage. For example, the gate driver may provide a scan signal to the sub-pixels SP1, SP2, and SP3 selected through the scan line, and the data driver may provide the data voltage to the sub-pixels SP1, SP2, and SP3 selected through the data line.

Pads 215a and 215b may be located on the non-display area NAA of the base substrate 110 and may include a plurality of electrode pads. The pads 215a and 215b may include the plurality of electrode pads for transmitting power and various signals for driving the display panel PNL from a plurality of printed circuit boards 230, 250a and 250b to the display area AA. For example, the plurality of electrode pads may include a plurality of power supply pads, a plurality of data supply pads, a control signal supply pad, a touch signal detection pad, or a plurality of common power supply pads. Embodiments of the present disclosure are not limited thereto. The plurality of printed circuit boards 230, 250a, and 250b may include a first printed circuit board 230, a second printed circuit board 250a, and a third printed circuit board 250b. The pads 215a and 215b may include a first pad 215a and a second pad 215b. In an embodiment, the plurality of printed circuit boards 230, 250a, 250b may include more printed circuit boards 230, 250a, 250b on one side of the display panel PNL than the other, such as in FIG. 4. Further, the pads 215a, 215b may be pad areas that extend along an entirety of the non-active area NAA proximate the printed circuit boards 230, 250a, 250b, or may be individual pad locations or separate pad areas corresponding to the printed circuit boards 230, 250a, 250b

A plurality of flexible printed circuit boards 220, 240a, 240b, and 260 may be attached to each of the first and second pads 215a and 215b. An integrated circuit chip may be disposed in each of the plurality of flexible printed circuit boards 220, 240a, 240b, 260. In one example, each of the plurality of flexible printed circuit boards 220, 240a, 240b, and 260 may be attached to the first and second pads 215a and 215b using an anisotropic conductive film, a conductive double-sided tape, or a conductive tape. The plurality of flexible printed circuit boards 220, 240a, 240b, and 260 may include a first flexible printed circuit board 220, a second flexible printed circuit board 240a, a third flexible printed circuit board 240b, and a first ground flexible printed circuit board 260.

Each of the plurality of printed circuit boards 230, 250a, and 250b may be attached to the other side (i.e., a rear or bottom side) of each of the plurality of flexible printed circuit boards 220, 240a, 240b, and 260. The rear or bottom side of the plurality of flexible printed circuit boards 220, 240a, 240b, and 260 may be opposite to one side (i.e., a front side) of each of the plurality of flexible printed circuit boards 220, 240a, 240b, and 260 that is attached to the pads 215a and 215b. Each of the plurality of printed circuit boards 230, 250a, and 250b may be electrically connected to each of the plurality of flexible printed circuit boards 220, 240a, 240b, and 260 via each of pad electrodes 231, 251a, and 251b disposed on each of the plurality of printed circuit boards 230, 250a, and 250b. The pad electrodes 231, 251a, and 251b may include a first pad electrode 231, a second pad electrode 251a, and a third pad electrode 251b. For example, the first pad electrode 231 may be located on the first printed circuit board 230, and the second pad electrode 251a may be located on the second printed circuit board 250a. The third pad electrode 251b may be located on the third printed circuit board 250b.

In an embodiment, such as that shown in FIG. 4, one side of the display panel PNL, such as the left side LS, includes a single printed circuit board 230 with a single pad electrode 321 that each generally extend along at least a majority of, but more preferably substantially all of, a length of the corresponding side of the display panel PNL. The left side LS of the display panel PNL may include multiple flexible printed circuit boards 220 that electrically connect the single printed circuit board 230 to the pad 215a. In FIG. 4, there are four flexible printed circuit boards 220 spaced apart from each other, although other configurations may include more or less than four and with different spacing than that shown. The right side RS of the display panel PNL includes a single upper printed circuit board 250a and a single lower printed circuit board 250b, where the board 250b may be larger than the board 250a. A single flexible printed circuit board 240a is associated with the printed circuit board 250a with a single pad electrode therebetween. The lower printed circuit board 250b is associated with a single flexible printed circuit board 240b as well as a single ground flexible printed circuit board 260. A common single pad electrode 251b is between the lower printed circuit board 250b and both the flexible printed circuit board 240b and the ground flexible printed circuit board 260. The lower printed circuit board 250b may have a larger size relative to the upper printed circuit board 250a to accommodate both the flexible printed circuit board 240b and the ground flexible printed circuit board 260. The upper and lower circuit board assemblies 250a, 25a, 240a and 250b, 251b, 250b, 260 are spaced from each other on the right side RS of the display panel PNL and each generally occupy less than a majority of a length of the right side RS of the display panel PNL.

The first to third flexible printed circuit boards 220, 240a, and 240b may provide various powers and signals for driving the display panel PNL respectively supplied from the plurality of printed circuit boards 230, 250a, and 250b to the display area AA. For example, the various powers and signals may include a high-potential voltage, a low-potential voltage, a scan signal, a data signal, and a touch driving signal. The first ground flexible printed circuit board 260 may emit static electricity to the outside.

The first printed circuit board 230 may be located on one side end of the first display area 100a-f and may be a source PCB S-PCB as a controller for driving the display panel PNL. The source PCB may include a source driver integrated circuit for driving the data lines formed on the display panel PNL. For example, the second printed circuit board 250a and the third printed circuit board 250b may be located on one side end of the second display area 100b-f and may be a touch PCB or a main board as a controller for driving the touch sensing area TS. However, embodiments of the present disclosure are not limited thereto.

Referring to FIG. 6, the transistor TR may be disposed on the base substrate 110. The transistor TR may include a semiconductor layer ACT, a gate insulating layer 111, a gate electrode GE, a source electrode SE, and a drain electrode DE. The base substrate 110 may further include a buffer layer that reduces or prevents foreign substances or moisture from penetrating into the transistor TR. The buffer layer may be composed of a single layer or one or more multiple layers of an insulating material.

The semiconductor layer ACT may include an oxide semiconductor or silicon-based semiconductor material. For example, the semiconductor layer ACT may include a transparent oxide semiconductor material such as indium gallium zinc oxide (IGZO) or indium zinc oxide (IZO). The semiconductor layer ACT may include a channel area CA, a source area SA, and a drain area DA. The first insulating layer 111 may be composed of a single layer or a plurality of layers made of silicon oxide (SiOₓ) or silicon nitride (SiNₓ). However, embodiments of the present disclosure are not limited thereto. The base substrate 110 may further include a light blocking layer which may be located under the semiconductor layer ACT and overlap at least the channel area to prevent external light from being incident in the semiconductor layer ACT.

A first insulating layer 111 may be disposed between the semiconductor layer ACT and the gate electrode GE. Accordingly, a top surface and both opposing side surfaces of the semiconductor layer ACT are not exposed to the outside.

The gate electrode GE may be disposed on the first insulating layer 111. The gate electrode GE may overlap the channel area CA of the semiconductor layer ACT in a vertical direction. The gate electrode GE may be formed as a single layer or multiple layers made of one of molybdenum (Mo), aluminum (Al), chromium (Cr), gold (Au), titanium (Ti), nickel (Ni), neodymium (Nd), copper (Cu) or an alloy thereof.

An interlayer insulating layer 113 may be disposed on the gate electrode GE. The interlayer insulating layer 113 insulates the gate electrode GE and may be composed of a single layer or a plurality of layers made of an inorganic insulating material such as silicon oxide (SiOₓ) or silicon nitride (SiNₓ). However, embodiments of the present disclosure are not limited thereto.

Each of first contact holes CH1 may extend through the interlayer insulating layer 113 and the first insulating layer 111 so as to expose a portion of a surface of each of the source area SA and the drain area DA of the semiconductor layer ACT.

Each of the source electrode SE and the drain electrode DE may fill each of the first contact holes CH1 and extend along and on an upper surface of the interlayer insulating layer 113. The source electrode SE and drain electrode DE may be respectively disposed on both opposing sides of the gate electrode GE, and may be connected to the source area SA and the drain area DA, respectively.

A planarization layer 115 may be disposed on the interlayer insulating layer 113, the source electrode SE, and the drain electrode DE. The planarization layer 115 may include a first planarization layer 114 and a second planarization layer 116. The planarization layer 115 serves to planarize a step caused by the underlying circuit element including the transistor TR. The planarization layer 115 may include an organic insulating material such as acryl resin, epoxy resin, phenolic resin, polyamide resin, or polyimide resin. However, the present disclosure is not limited thereto, and the planarization layer 115 may include an organic insulating material capable of planarizing the step.

A second contact hole CH2 may extend through the first planarization layer 114 and the second planarization layer 116 of the planarization layer 115 so as to exposes a portion of a surface of the drain electrode DE of the transistor TR. However, However, the present disclosure is not limited thereto. For example, a portion of the surface of the source electrode SE may be exposed through the second contact hole CH2.

The light-emitting element area ED may be disposed on the planarization layer 115. The light-emitting element area ED may include a first electrode AND, a light-emitting layer EL, a second electrode CTH, and a bank 117. The first electrode AND may be referred to as an anode electrode or a pixel electrode, and the second electrode CTH may be referred to as a cathode electrode or a counter electrode.

The first electrode AND may be positioned on the second planarization layer 116. The first electrode AND may extend toward the second contact hole CH2. Accordingly, the first electrode AND may be electrically connected to the drain electrode DE. The first electrode AND may include a transparent metal oxide such as indium tin oxide (ITO) or indium zinc oxide (IZO). Alternatively, the first electrode AND may have a single-layer or multi-layer structure including a reflective metal film made of silver (Ag), aluminum (Al), gold (Au), nickel (Ni), chromium (Cr), or alloys thereof.

The bank 117 may be disposed on the second planarization layer 116. The bank 117 may distinguish he sub-pixels SP1, SP2, and SP3 (see FIG. 4) from each other. To this end, the bank 117 may be formed to cover an edge of the first electrode AND. The bank 117 may have a bank hole 117a defined therein exposing a portion of the surface of the first electrode AND. A portion of the first electrode AND exposed through the bank hole 117a may be a light-emitting area. Further, the bank 117 may prevent light beams of different colors from adjacent sub-pixels from being mixed with each other. The bank 117 may include an organic insulating film such as polyimide or epoxy. Furthermore, the bank 117 may include an opaque resin, for example, black resin.

The light-emitting layer EL may be disposed on the first electrode AND. In one example, the light-emitting layer EL may be made of an organic material that emits white light, and may display one color among red, green, or blue via a color filter disposed on top thereof. In one embodiment, the light-emitting layer EL may be formed over an entirety of the display area AA while covering an exposed surface of each of the first electrode AND and the bank 117.

The light-emitting layer EL include a stack structure of a hole transport layer HTL, an emission material layer EML, an electron transport layer ETL, a hole blocking layer HBL, a hole injection layer HIL, an electron blocking layer EBL, and an electron injecting layer EIL. The light-emitting layer EML in the stack structure of the light-emitting layer EL may emit light based on recombination of holes injected from the first electrode AND and electrons injected from the second electrode CTH.

The second electrode CTH may be disposed on the light-emitting layer EL. The second electrode CTH may be formed to cover the light-emitting layer EL. The second electrode CTH may be formed across all of the plurality of pixels PX (see FIG. 4). The second electrode CTH may include a transparent metal oxide such as indium-tin-oxide (ITO) or indium-zinc-oxide (IZO). Alternatively, the second electrode CTH may have a single-layer or multi-layer structure including a reflective metal film made of silver (Ag), aluminum (Al), gold (Au), nickel (Ni), chromium (Cr), or alloys thereof.

The encapsulation area 140 may be disposed on the light-emitting element area ED. The encapsulation area 140 may protect the light-emitting element area ED and the transistor TR from external oxygen or moisture. The encapsulation area 140 may include a multi-layer structure in which a first encapsulation layer 131, a second encapsulation layer 133, and a third encapsulation layer 135 are stacked.

The second encapsulation layer 133 may be interposed between the first encapsulation layer 131 and the third encapsulation layer 135. Each of the first encapsulation layer 131 and the third encapsulation layer 135 may include an inorganic insulating material. For example, each of the first encapsulation layer 131 and the third encapsulation layer 135 may include at least one of silicon nitride (SiNₓ), silicon oxide (SiOₓ), or silicon oxynitride (SiON). The first encapsulation layer 131 may be disposed on the second electrode CTH. The second encapsulation layer 133 may be located on the first encapsulation layer 131 and may planarize a surface. To this end, the second encapsulation layer 133 may include an organic insulating material. For example, the second encapsulation layer 133 may include at least one of epoxy, polyimide, polyethylene, or acrylate. The second encapsulation layer 133 may prevent foreign substances from penetrating into the light-emitting element area ED or the transistor TR.

The touch sensing area TS may be disposed on the third encapsulation layer 135. The touch sensing area TS may include a touch buffer film 151, a bridge electrode 152, a plurality of touch electrodes 153 and 155, a touch interlayer insulating layer 154, and a touch protective film 159. The plurality of touch electrodes 153 and 155 may include the first touch electrode 153 and the second touch electrode 155. The plurality of touch electrodes 153 and 155 and the bridge electrode 152 may be located in different layers. The plurality of first touch electrodes 153 and the plurality of second touch electrodes 137 may be disposed to be spaced apart from each other. Adjacent ones of a plurality of first touch electrodes 133 disposed adjacent to each other may be electrically connected to each other via the bridge electrode 152 located in a different layer from a layer of the plurality of first touch electrodes 133. The bridge electrode 152 may extend through the touch interlayer insulating layer 154 so as to contact the first touch electrode 133.

The touch protective film 159 may be disposed to cover the plurality of first and second touch electrodes 153 and 155. The touch protective film 159 may include an organic insulating material.

In the display device 1000 including the touch sensing area TS, an input signal may be transmitted to the display area using various devices, systems, methods, and schemes other than touching with a finger.

An active pen may be included as one example device, system, method, or scheme of transmitting the input signal. For example, the input signal may be transmitted to the display area by the user touching the display area with the active pen. The input signal transmitted to the display area may be sensed by the touch electrodes of the touch sensing area TS.

The input signal may be transmitted to the display area in a scheme other than the scheme of directly contacting the display area with the pen or the finger. For example, the input signal may be transmitted to the display area in a hovering scheme. In the hovering scheme, the input signal may be transmitted to the display area even when the finger or the active pen is spaced, by a predetermined distance, typically on the order of several millimeters (i.e., 1 mm to 15 mm, and more preferably at least 5 mm) from the display area. A specific command such as zooming in or zooming out may be input via a gesture. In the hovering scheme, the input signal may be transmitted to the touch sensing area without direct contact with the display area. In this regard, change in current detected in the touch sensing area may be sensed and the display area may operate based on the sensed result. In an embodiment, the change in current is caused by characteristics of the active pen and the touch sensing area.

In some examples, as a thickness of the display panel becomes smaller or decreases, influence of the noise generated when the display device operates on the active pen increases, thereby deteriorating the performance of the active pen. In other words, thinner display panels tend to produce more noise when a pen is used on the display panel. This will be described with reference to the drawings.

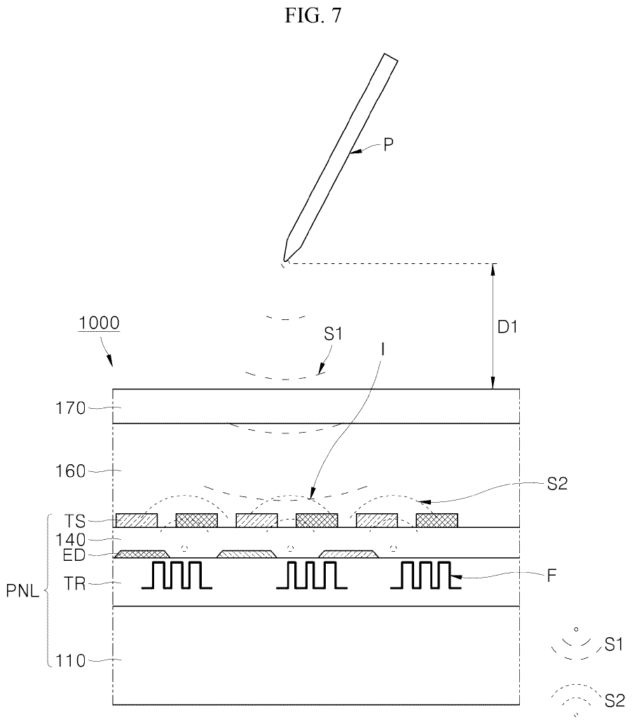

FIG. 7 is a diagram showing signal input of an active pen on a display device according to an embodiment of the present disclosure.

Referring to FIG. 7, an active pen P may perform a hover operation at a position spaced by a predetermined distance D1 from the cover substrate 170 of the display device 1000. In an embodiment, the predetermined distance may be 1 mm to 20 mm, and is more preferably at least 5 mm. The distance D1 may also be different for different operations. For example, hovering closer to the display may be associated with a zoom in function while hovering further from the display may be associated with a zoom out function. In FIG. 7, the hover operation of the active pen P may be performed when the distance D1 is at least 5 mm from the cover substrate 170.

In order to execute a specific command via the hover motion, the active pen P transmits an input signal S1 to the display device 1000. The input signal S1 of the active pen P may have a first operation frequency. For example, the first operation frequency generated from the active pen P may range from 18 kHz to 200 kHz. In response thereto, the display panel PNL of the display device 1000 may transmit the signal provided through the driver to the light-emitting element area ED which may emit light to display an image or video.

Various noises S2 may occur inside the display panel PNL. For example, the noises S2 may include common noise and pattern noise. The common noise is circuit noise related to the frequency F at which the display panel PNL operates, and may include noise generated depending on a frequency at which the integrated circuit chip operates, a frame frequency, or a grounding status. The pattern noise may occur due to transition in the data voltage generated according to the pattern. Furthermore, the noises S2 may include noise that may occur due to a voltage drop (IR drop) of a ground power VSS and a noise that may occur when the touch sensing area TS detects the input signal. These noises S2 may have different operation frequencies.

For example, when the operation frequency of the noise S2 and the first operation frequency of the input signal S1 of the active pen P overlap each other, an interference I occurs between the two signals S1 and S2. As the thickness of the display panel PNL becomes smaller or decreases, a distance between the touch sensing area TS and the cover substrate 170 of the display device 1000 may become smaller. The interference phenomenon between the input signal S1 of the active pen P and the noise S2 generated from the touch sensing area TS may become greater, thereby reducing the signal level of the active pen P. The increase in the interference phenomenon may be the result of the closer proximity of the touch sensing area TA and the cover substrate 170 producing more overlap between the signals S1, S2, or the decrease in thickness of the sealing layer 160 or other layers attenuating the signals S1, S2 to a lesser degree (i.e., the signals are stronger due to less interference traveling through thinner layers), or both. Other factors may also contributed to the increase in the interference phenomenon. As the noise S2 level increases, the signal level of the active pen P may further decrease. In an embodiment, the signal level S1 associated with the active pen P may generally be constant, but the stronger noise S2 signal may reduce the effect of the signal level S1 associated with the active pen P. Accordingly, the hover operation of the active pen P should preferably be performed at a position spaced by the distance D1 of at least 5 mm from the cover substrate 170. However, where the signal level S1 is too strong, the hover operation may be performed only at a position spaced by the distance D1 of 2 mm from the cover substrate 170 due to the weakened signal level associated with the active pen P. At a position spaced by the distance D1 greater than 5 mm from the cover substrate 170, the signal level of the active pen P decreases and thus the display device 1000 does not recognize the input signal provided from the active pen P, so that the performance of the active pen P decreases. Thus, in a preferred embodiment, the distance D1 is in a range of 5 mm to 10 mm, and more preferably between 5 mm and 7 mm.

Referring again to FIG. 4 and FIG. 5, for example, as the size of the display panel PNL increases, a spacing between the first printed circuit board 230 disposed on one side (the left side) of the display panel PNL and a pixel disposed in the display area AA and on the other side (the right side) of the display panel PNL opposite to one side of the display panel PNL may be greater. Accordingly, in order to stably discharge the charge accumulated in the light-emitting element area ED of the display panel PNL to the outside, the first ground flexible printed circuit board 260 may be disposed on the other side (the right side) of the display panel PNL opposite to one side (the left side) of the display panel PNL on which the first printed circuit board 230 is disposed. The first ground flexible printed circuit board 260 may be attached to the third pad electrode 251b of the third printed circuit board 250b via a conductive tape. The charges accumulated inside the display panel PNL may be discharged to the outside through the first ground flexible printed circuit board 260, such that the contrast ratio of the display device may be improved and the noise of the touch sensing area TS (see FIG. 7) may be reduced or removed, and thus, the quality of the video or image may be maintained stably. In other words, the ground flexible printed circuit board 260 alleviates or overcomes the challenges discussed above with increasing interference in thinner displays, as well as improving contrast ratio of the display device. Additional details of the ground flexible printed circuit board 260 will be provided in the below description.

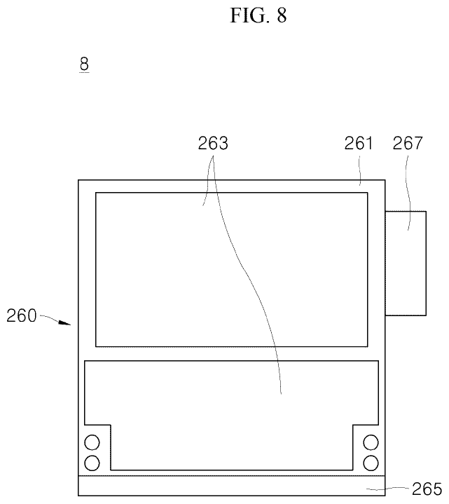

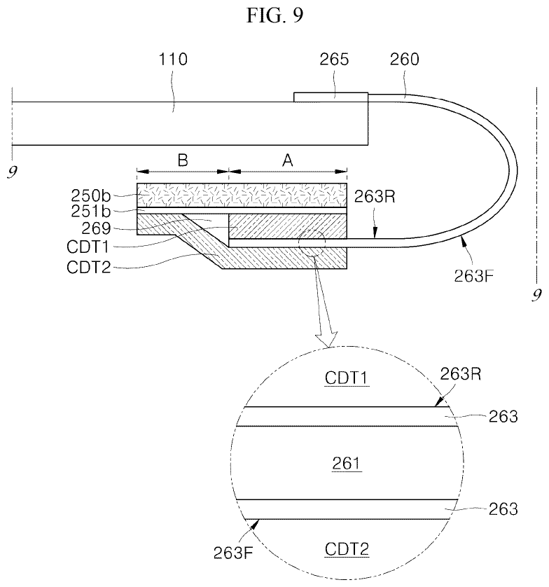

FIG. 8 is a diagram showing a ground flexible printed circuit board according to an embodiment of the present disclosure. FIG. 9 is a cross-sectional view along a line 9-9 in FIG. 5. In FIG. 9, for convenience of illustration, only the base substrate 110 is shown.

Referring to FIG. 8 and FIG. 9, the first ground flexible printed circuit board 260 according to an embodiment of the present disclosure may include a base film 261, a ground pattern 263, a ground pad 265, and a release film 267. The first ground flexible printed circuit board 260 according to an embodiment of the present disclosure may have a rectangular shape with a short side extending in the first direction and a long side extending in the second direction perpendicular to the first direction. However, embodiments of the present disclosure are not limited thereto.

The base film 261 of the first ground flexible printed circuit board 260 may include a plastic film that is flexible and includes an insulating material. For example, the plastic film may include polyimide PI. However, embodiments of the present disclosure are not limited thereto. The ground pattern 263 may be formed on the base film 261 in a printing manner. The ground pattern 263 may include a metal material to discharge charges accumulated in the display panel PNL to the outside. Thus, the ground pattern 263 may be a printed metal layer in a designated shape according to the selected printing pattern. For example, the metal material may include copper (Cu). For example, the ground pattern 263 may be formed on each of both opposing surfaces of the base film 261, may include a pattern extending through the base film 261, or may be patterned into multiple layers. In an embodiment, the opposing surfaces are opposing major surfaces having the largest surface area among the surfaces of the base film 261, which may be a top and bottom surface in the orientation of FIG. 8 and FIG. 9. The pattern may extend through an entirety of the base film 261, meaning that the pattern is printed into, and entirely through, the base film 261 in some embodiments to be exposed on both the opposing major surfaces. Further, the printing process may involve depositing multiple layers, such as a layer on a first major surface, an intervening layer through the base film 261, and a layer on the opposing second major surface, or any combination thereof.

The ground pad 265 may be electrically connected to the second pad 215b of the display panel PNL. The release film 267 may detach the ground flexible printed circuit board 260.

The ground pattern 263 may be electrically connected to the third pad electrode 251b of the third printed circuit board 250b. For example, referring to FIG. 9 and the detail view in FIG. 9, a partial area A of the third pad electrode 251b of the third printed circuit board 250b may be attached to one surface (i.e., a rear surface 263R) of the ground pattern 263 of the first ground flexible printed circuit board 260 via a conductive double-sided tape CDT1 and thus electrically connected thereto. Furthermore, the remaining area B of the third pad electrode 251b of the third printed circuit board 250b may be electrically connected to the first ground flexible printed circuit board 260 via a conductive tape CDT2 attached to the other surface (i.e., a front surface 263F) of the ground pattern 263 of the first ground flexible printed circuit board 260 and extending toward the remaining area B.

As shown in FIG. 9, the ground flexible printed circuit board (“FPCB”) 260 may be bent to make contact with the pad electrode 251b and the printed circuit board 250b underneath the display panel 110 via the conductive tapes CDT1, CDT2. Accordingly, once the ground FPCB 260 is bent, the rear surface 263R may be an upper or top surface and the front surface 263F may be a lower or bottom surface. The detail view in FIG. 9 provides additional detail regarding the layer stack at the interface between the ground FPCB 260 and the conductive tapes CDT1, CDT2. Specifically, the ground pattern 263 is printed or otherwise disposed on both opposing major surfaces of the base layer 261 with the ground pattern 263 in direct contact with a respective conductive tape CDT1, CDT2. Thus, from top to bottom, the interface is a multi-layer stack that includes the first conductive tape CDT1, an upper portion or layer of the ground pattern 263 (which may be the pattern 263 disposed on a rear surface of the base layer 261 prior to folding), the base layer 261, a lower portion or layer of the ground pattern 263 (which may be the pattern 263 disposed on a front surface of the baes layer 261 prior to folding), and the second conductive tape CDT2.

In addition, the first conductive tape CDT1 may terminate after the area A on the pad electrode 251b (i.e., at the interface between area A and area B), but the second conduct tape CDT2 may extend across all of area A and continue into area B. At the outer end or termination point of the first conductive tape CDT1 where the tapes CDT1, CDT2 no longer overlap, the second conductive tape CDT2 may have a step down configuration or a tapered configuration to extend across and overlap a thickness of the ground FPCB 260 and the first conductive tape CDT1 to directly contact the pad electrode 251b. In some embodiments, there may be a small air gap or space 269 between the termination point or outer edge of the ground FPCB 260 and the first tape CDT1 and the second tape CDT2.

Each of the conductive double-sided tape CDT1 and the conductive tape CDT2 may be prepared by dispersing a conductive material in a polymer resin including adhesiveness. For example, the conductive material may include carbon black, graphite, silver, copper, nickel, aluminum, etc.

The charge accumulated inside the display panel PNL may be discharged to the outside through the first ground flexible printed circuit board 260 connected to the third printed circuit board 250b.

In some examples, depending on a type of the adhesive polymer resin constituting the conductive double-sided tape or the conductive tape a type of the material constituting the conductive material, a resistance value may not be uniform and may vary. Furthermore, the resistance value may also vary depending on the adhesive performance of the conductive double-sided tape or the conductive tape. For example, when the adhesive strength decreases, the resistance value may change from an initial resistance value.

When the resistance value is not maintained uniformly and has variation, it may be difficult to implement a uniform contrast ratio across the entirety of the display area AA of the display panel PNL. Furthermore, when the resistance value changes, it may become difficult to reduce or eliminate the noise generated during a touch operation. Then, as the interference with the signal level of the active pen continues to occur, it may be difficult to maintain the performance of the active pen.

Accordingly, one or more embodiments may overcome such challenges with an impedance matching configuration that allows a resistance value of the first printed circuit board 230 attached to one side of the display panel PNL and a resistance value of the third printed circuit board 250b spaced from the first printed circuit board 230 and located on the other side of the display panel PNL to be equal to each other.

The impedance matching means that when connecting one output terminal (e.g., the first printed circuit board 230) and one input terminal (e.g., the third printed circuit board 250b) to each other, a difference between impedances thereof is reduced to lower noise caused by the difference. When impedance matching is not achieved, the level of noise may increase such that the performance of the display panel may deteriorate.

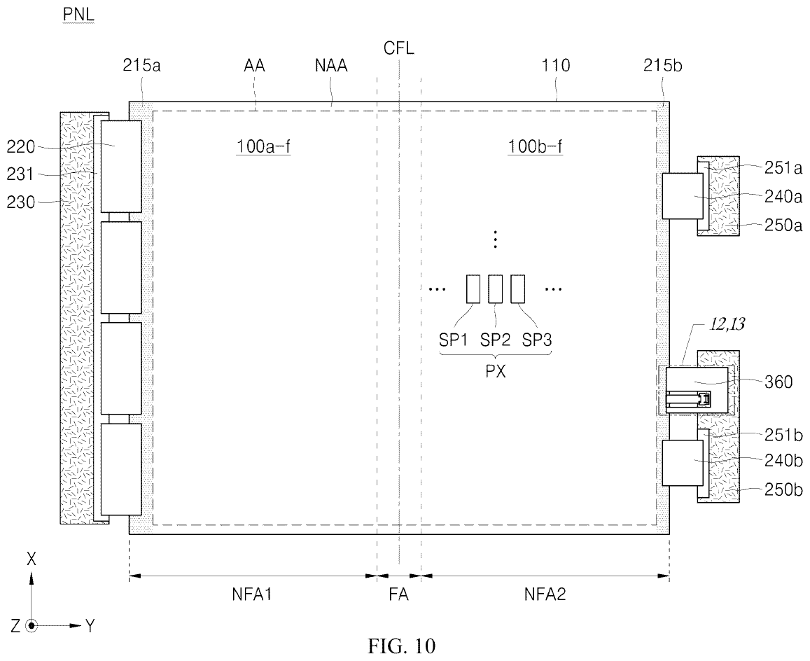

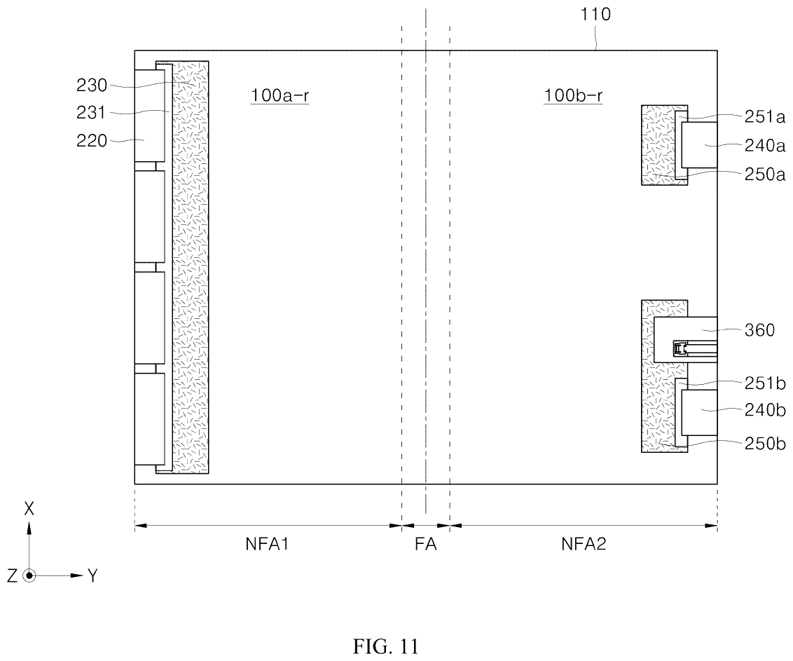

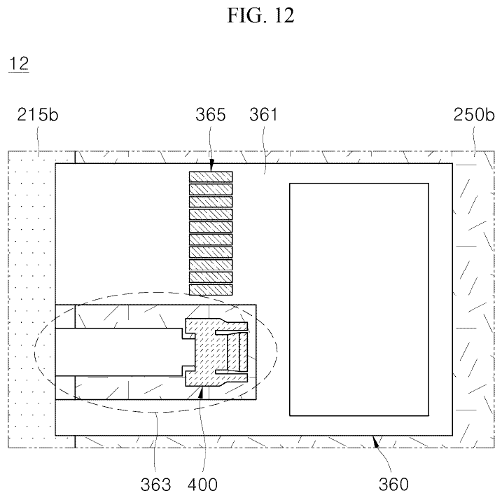

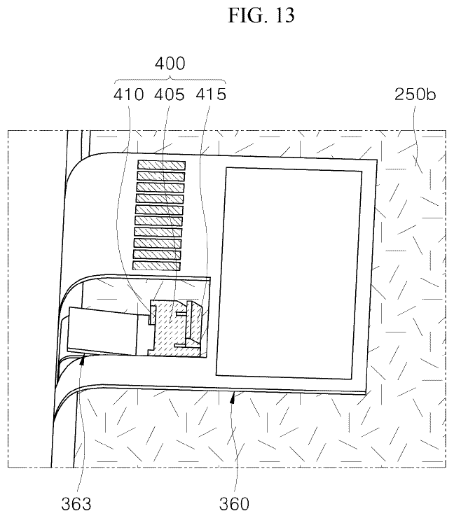

FIG. 10 is a front plan view showing a portion of the display panel according to another embodiment of the present disclosure. FIG. 11 is a rear plan view showing the display panel in FIG. 10. FIG. 12 and FIG. 13 are enlarged views of an area 12 in FIG. 10. FIG. 10 and FIG. 11 include the same configuration as that of FIG. 4 and FIG. 5 except for a shape of the second ground flexible printed circuit board. Thus, duplicate descriptions are omitted or briefly set forth, and differences are mainly described below. The same reference numerals may indicate the same components.

Referring to FIG. 10 and FIG. 11, the display area AA may have the first display area 100a-f located at a left side around the center folding line CFL and the second display area 100b-f located at a right side around the center folding line CFL. However, the present disclosure is not limited thereto. In the display area AA, the plurality of pixels PX may be arranged, each including a plurality of sub-pixels SP1, SP2, and SP3. Videos or images may be displayed from the display area AA based on light beams of different colors emitted from the plurality of pixels PX.

The first flexible printed circuit board 220 and the first printed circuit board 230 may be disposed on one edge of the first display area 100a-f. The first printed circuit board 230 may be a source PCB S-PCB as a controller for operating the display panel PNL.

The second flexible printed circuit board 240a electrically connected to the second printed circuit board 250a may be disposed on the second display area 100b-f opposite to the first display area 100a-f on which the first printed circuit board 230 is disposed. The second printed circuit board 250a may be a touch PCB or a main board as a controller for operating the touch sensing area. However, embodiments of the present disclosure are not limited thereto. Furthermore, the third printed circuit board 250b may be disposed at a location spaced apart from the second printed circuit board 250a in the first direction (e.g., X-axis direction). The third printed circuit board 250b may be connected to the display panel PNL via the third flexible printed circuit board 240b. In FIG. 10, the ground FPCB 360 may be disposed similarly to the ground FPCB 260 discussed above, meaning outside of the display device in the Y-direction. In FIG. 11, the ground FPCB 360 may be disposed above or below the display panel PNL and thus may overlap the display panel PNL, as also described above.

Referring to FIG. 12, the third printed circuit board 250b may include a connector structure 400 (or connector assembly 400 or fastener assembly 400). Referring to FIG. 13, the connector structure 400 may include a housing 405 having an inner space 410 defined therein and an actuator 415 connected to the housing 405. The housing 405 may constitute an outer appearance of the connector structure 400. The housing 405 may include an insulating material. The housing 405 may have the inner space 410 defined therein capable of accommodating therein the second ground flexible printed circuit board 360. At one side of the housing 405, an insertion hole may be defined through which the second ground flexible printed circuit board 360 is inserted.

A plurality of connection terminals (not shown) may be disposed on a surface of the third printed circuit board 250b corresponding to the inner space 410 of the housing unit 400. The plurality of connection terminals may include a plurality of metal patterns electrically connected to the second ground flexible printed circuit board 360.

At the other side of the housing 405, the actuator 415 may be disposed. The actuator 415 may allow the second ground flexible printed circuit board 360 to contact the plurality of connection terminals of the third printed circuit board 250b and thus to be electrically connected to the third printed circuit board 250b. The actuator 415 may remove the second ground flexible printed circuit board 360 from the third printed circuit board 250b. The actuator 415 may pivot in upward and downward directions and may include a spring or an elastic material such as plastic to selectively apply pressure to the second ground FPCB 360 to ensure contact between the ground FPCB 360 and the connection terminals on the printed circuit board 250b. For example, the actuator 415 may pivot to a first position to allow the second ground flexible printed circuit board 360 and the third printed circuit board 250b to contact each other. The actuator 415 may pivot to a second position to remove the second ground flexible printed circuit board 360 from the third printed circuit board 250b. A vertical level of the first position may be higher than that of the second position. However, embodiments of the present disclosure are not limited thereto. The vertical level of the first position may be lower than that of the second position.

The connector structure 400 may allow the second ground flexible printed circuit board 360 to be in direct contact with the connection terminal made of the metal material of the third printed circuit board 250b. Accordingly, the resistance value may be prevented from changing compared to the case where the second ground flexible printed circuit board 360 is attached to the third printed circuit board 250b using the conductive double-sided tape or conductive tape.

Furthermore, the second ground flexible printed circuit board 360 may be configured to include a plurality of resistance patterns to implement impedance matching with the first printed circuit board 230. This will be described with reference to the drawings.

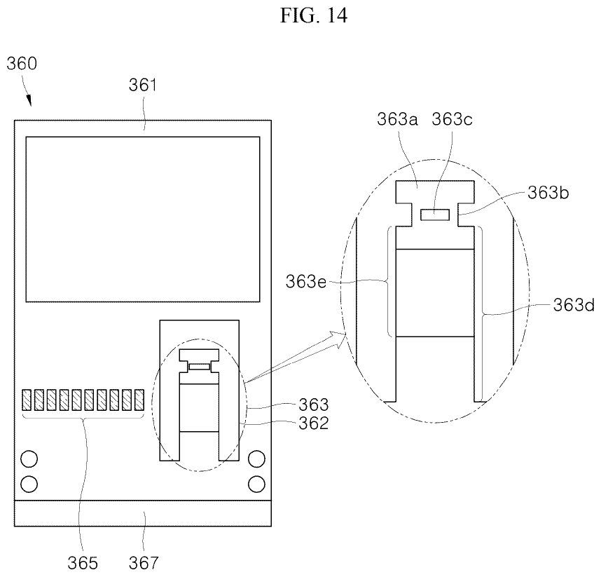

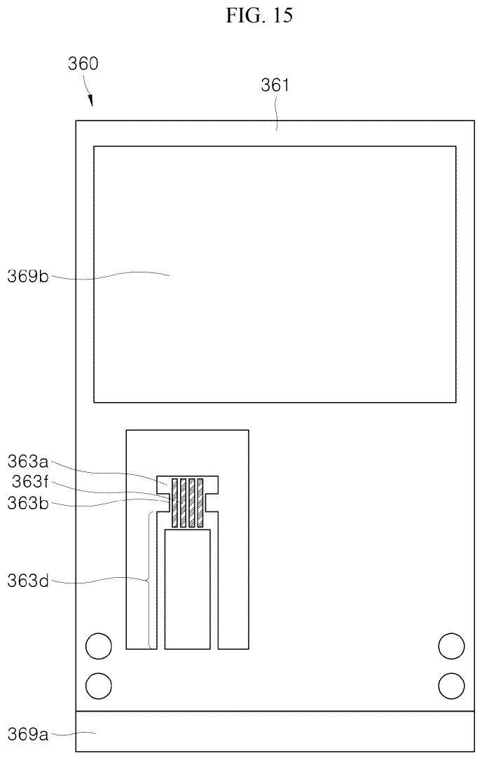

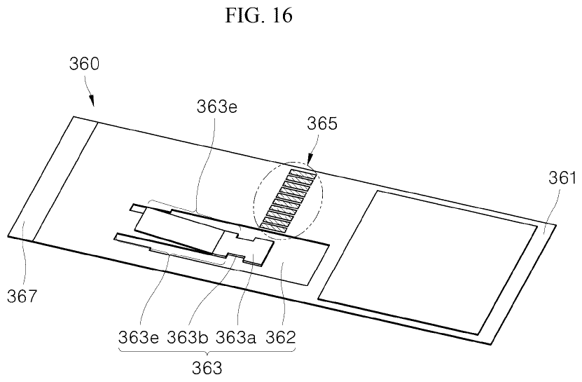

FIGS. 14 to 16 are drawings showing a second ground flexible printed circuit board according to another embodiment of the present disclosure. FIG. 14 is a diagram showing a front portion or front surface of the second ground flexible printed circuit board. FIG. 15 is a diagram showing a rear portion or rear surface of the second ground flexible printed circuit board. FIG. 16 is a perspective view of the second ground flexible printed circuit board.

Referring to FIGS. 14 to 16, the second ground flexible printed circuit board 360 may include a base film 361, an opening 362 defined in the base film 361, a terminal 363 extending so as to overlap with the opening 362, a plurality of resistance patterns 365, a ground pad 367, and adhesive members 369a and 369b. The second ground flexible printed circuit board 360 according to another embodiment of the present disclosure may have a rectangular shape with a short side extending in the first direction and a long side extending in the second direction. However, embodiments of the present disclosure are not limited thereto.

The base film 361 may include a plastic film that is flexible and includes an insulating material. For example, the plastic film may include polyimide (PI). However, embodiments of the present disclosure are not limited thereto.

The opening 362 may be disposed in the base film 361. The opening 362 may have a polygonal shape and extend through the base film 361. The terminal 363 extending from the base film 361 may be disposed at one side end of the opening 362. The terminal 363 may be integrated with the base film 361. The terminal 363 may extend from one side end of the opening 362 in the first direction (e.g., X-axis direction) of the base film 361.

The terminal 363 may include a head portion 363a, a middle portion 363b, a fastening portion 363c, a body portion 363d, a cover portion 363e, and a plurality of metal terminal pattern portions 363f. The terminal 363 extends from the base film 361 and may have flexible properties. The head portion 363a and the middle portion 363b may be accommodated in the housing 405 of the connector structure 400 (see FIG. 13). The head portion 363a of the terminal 363 has a width larger than the width of the middle portion 363b and may be stably accommodated in the space 405 of the connector structure 400. The body portion 363d may extend from the middle portion 363b to the base film 361. The body portion 363d may be bent depending on the material of the flexible base film 361. Accordingly, the terminal 363 and the connector structure 400 may be fastened to each other via deformation of the body portion 363d.

The cover portion 363e has the same shape as a combination of the head portion 363a and the middle portion 363b of the terminal 363, and may cover a combination of the head portion 363a and the middle portion 363b. The cover portion 363e may be made of a material that is relatively stiffer than that of each of the head portion 363a and the middle portion 363b of the terminal 363 which are flexible. Accordingly, the head portion 363a and the middle portion 363b of the terminal 363 may be easily coupled to the connector structure 400.

The head portion 363a and the middle portion 363b of the terminal 363 may be fastened and fixed to the connector structure 400 via the fastening portion 363c. However, the present disclosure is not limited thereto.

After the terminal 363 is fastened to the connector structure 400, the actuator 415 of the connector structure 400 may pivot in one direction to fix a state in which the second ground flexible printed circuit board 360 and the third printed circuit board 250b contact each other.

Referring to FIG. 15, the plurality of metal terminal patterns 363f may be disposed on a back surface of the terminal 363. The plurality of metal terminal patterns 363f may extend from the head portion 363a of the terminal 363 to the middle portion 363b and may extend to a portion of the body portion 363d. When fastening the terminal 363 to the connector structure 400, the plurality of metal terminal patterns 363f may come into contact with the plurality of connection terminals disposed on the third printed circuit board 250b, such that the third printed circuit board 250b may be electrically connected to the second ground flexible printed circuit board 360. The plurality of metal terminal patterns 363f may include copper. However, embodiments of the present disclosure are not limited thereto.

The ground pad 367 may be disposed on one side end of a front surface of the base film 361. The ground pad 367 may include a plurality of pad metals. The ground pad 367 may electrically connect one side end of the second ground flexible printed circuit board 360 to the display panel PNL. Accordingly, the charges accumulated inside the display panel PNL may be discharged to the outside via the second ground flexible printed circuit board 360 connected to the third printed circuit board 250b.

The plurality of resistance patterns 365 may be disposed on the front surface of the base film 361. For example, the plurality of resistance patterns 365 may be spaced apart from each other and may be disposed on one side of the opening 362. The plurality of resistance patterns 365 may provide a resistance value required for impedance matching in the display panel PNL. For example, the plurality of resistance patterns 365 may provide different resistance values. Accordingly, the resistance value required for the impedance matching in the display panel PNL may be selected and provided. In an embodiment of the present disclosure, a configuration in which 10 resistance patterns 365 are arranged is presented. However, the present disclosure is not limited thereto.

The adhesive members 369a and 369b may be respectable disposed in both edge portions of the back surface of the second ground flexible printed circuit board 360 to prevent movement of the second ground flexible printed circuit board 360 under an external force after the second ground flexible printed circuit board 360 has been fastened to the third printed circuit board 250b.

Accordingly, in another embodiment of the present disclosure, the connector structure 400 may be capable of connecting and fixing the second ground flexible printed circuit board 360 to the third printed circuit board 250b in a direct contact manner with the third printed circuit board 250b. Accordingly, the resistance value may be prevented from changing, compared to a case when using the conductive double-sided tape or the conductive tape. Furthermore, the second ground flexible printed circuit board 360 may include the plurality of resistance patterns to provide the resistance value required for the impedance matching in the display panel PNL, thereby implementing the impedance matching thereof with the first printed circuit board 230.

The impedance matching may be able to be implemented, such that the quality of the video or image of the display device may be improved, and the performance of the active pen may be improved.

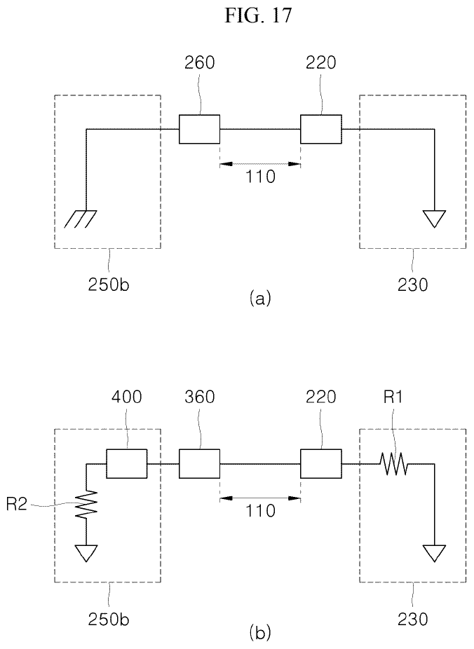

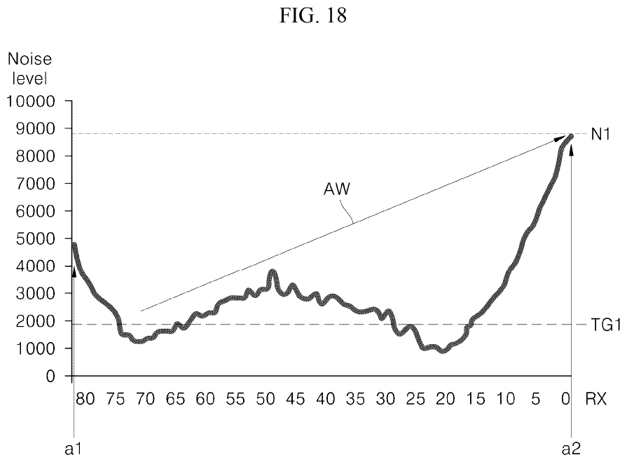

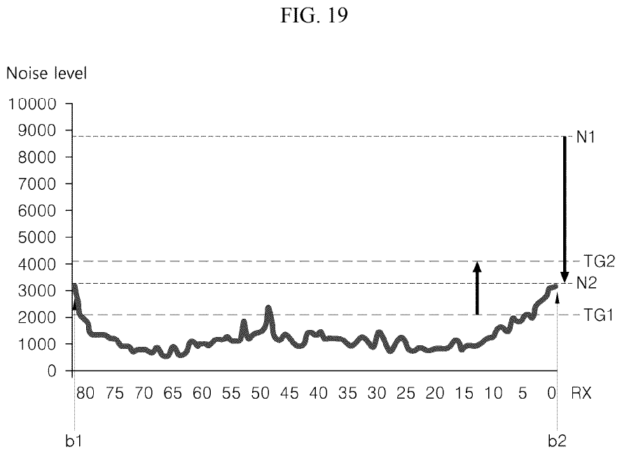

FIG. 17 is a diagram showing impedance matching based on a connection structure of the ground flexible printed circuit board in accordance with the embodiments of the present disclosure. FIG. 18 and FIG. 19 are graphs showing a noise level and a signal level of the active pen according to embodiments of the present disclosure. For example, FIG. 18 is a graph showing the noise level and the signal level of the active pen in a display device including the first ground flexible printed circuit board according to an embodiment of the present disclosure. FIG. 19 is a graph showing the noise level and the signal level of the active pen in a display device including the second ground flexible printed circuit board according to another embodiment of the present disclosure.

Referring to FIG. 17 and FIG. 18, according to an embodiment of the present disclosure, the first printed circuit board 230 including a source PCB may be connected to one side of the display panel 110 via the first flexible printed circuit board 220. The third printed circuit board 250b including a touch PCB or main board may be connected to the other side of the display panel 110 via the first ground flexible printed circuit board 260 according to an embodiment of the present disclosure (see (a) in FIG. 17).

The first ground flexible printed circuit board 260 may be attached to the third printed circuit board 250b using the conductive double-sided tape CDT1 or the conductive tape CDT2, as shown in FIG. 9. The conductive double-sided tape or the conductive tape may be prepared by dispersing a conductive material in a polymer resin including adhesiveness. However, the resistance may not be uniform and may vary depending on a material of the polymer resin including the adhesive or the conductive material that constitutes the conductive double-sided tape. Furthermore, the resistance may also vary depending on the adhesive force of the conductive double-sided tape.

When the resistance is not maintained uniformly and the variation in resistance becomes greater depending on the position of the display panel PNL, the variation in voltage depending on the position of the display panel PNL increases, such that the contrast ratio decreases and thus the quality of the video or image deteriorates. Furthermore, the noise may occur and increase as the voltage drop (IR drop) of the ground power VSS depending on the location of the display panel PNL occurs. As the noise increases, the interference between the active pen's input signal and the noise increases, such that the signal level of the active pen decreases, which may cause the display panel to not recognize the signal from the active pen.

For example, as shown in FIG. 18, it may be identified that as a position in the display panel PNL (see FIG. 10) shifts from a first position a1 in the display panel PNL closer to the first printed circuit board 230 and the source PCB to a second position a2 in the display panel PNL farther away from the first printed circuit board 230, a first noise level N1 increases as indicated by arrow AW. As the first noise level N1 increases, a first signal level TG1 of the active pen at a position spaced from the cover substrate 170 by a distance (D1, see FIG. 7) larger than 5 mm may fall below 2000 kHz. As the first signal level TG1 of the active pen falls below 2000 kHz, the display panel PNL may not be able to recognize the hover motion of the active pen.

In this regard, referring to (b) in FIG. 17, the first printed circuit board 230 is connected to one side of the display panel 110 via the first flexible printed circuit board 220. The third printed circuit board 250b is connected to the other side opposite to one side of the display panel 110 via the second ground flexible printed circuit board 360 according to another embodiment of the present disclosure directly connected to the connector structure 400 included in the third printed circuit board 250b. In this regard, the first printed circuit board 230 may include the source PCB, and the third printed circuit board 250b may include the touch PCB or the main board.

When the second ground flexible printed circuit board 360 is directly connected to the third printed circuit board 250b via the connector structure 400, a first resistance value R1 of the first printed circuit board 230 may be maintained to be equal to a second resistance value R2 of the third printed circuit board 250b.

When the resistance values R1 and R2 of the first printed circuit board 230 and the third printed circuit board 250b spaced apart from each other may be maintained to be equal to each other, the deviation in the voltage may be reduced or eliminated, such that the contrast ratio may be improved, thereby improving the quality of the video or image. Furthermore, the voltage drop of the ground power depending on the location of the display panel PNL may be reduced or prevented, thereby reducing or eliminating the noise. When the noise is reduced or eliminated, the signal level of the active pen increases, thereby allowing the display panel to easily recognize the signal from the active pen at a desired distance.

For example, as shown in FIG. 19, it may be identified that as a position in the display panel PNL (see FIG. 10) shifts from a first position b1 in the display panel PNL closer to the first printed circuit board 230 and the source PCB to a second position b2 in the display panel PNL farther away from the first printed circuit board 230, a second noise level N2 is substantially uniform. Furthermore, it may be identified that the second noise level N2 is significantly lower than the first noise level N1. When the second noise level N2 is reduced, the signal level of the active pen may increase. For example, a second signal level TG2 of the active pen at a position spaced from the cover substrate 170 by a distance (D1, see FIG. 7) larger than 5 mm may be greater than 4000 kHz. Furthermore, the second signal level TG2 of the active pen is greater than the first signal level TG1. Accordingly, the hover motion of the active pen performed at the position spaced from the cover substrate 170 by a distance (D1, see FIG. 7) larger than 5 mm may be recognized by the display panel PNL. Thus, the performance of the active pen may be improved.

According to embodiments of the present disclosure, the charge accumulated inside the display panel may be discharged to the outside via the ground flexible printed circuit board connected to the printed circuit board.

Furthermore, according to the embodiments of the present disclosure, the resistance value of the first printed circuit board located on one side of the display panel and the resistance value of the third printed circuit board disposed far away from the first printed circuit board may be maintained to be equal to each other via the impedance matching. Accordingly, the uniform contrast ratio may be implemented across the entire display area of the display panel. In addition, reducing or eliminating the noise generated during the touch operation may result in reducing or eliminating the interference with the signal level of the active pen, such that the performance of the active pen may be improved.

One aspect of the present disclosure provides a display device comprising: a display panel including a display area including a plurality of pixels, wherein the display panel has both opposing sides; a first printed circuit board disposed on one of the both opposing sides; a second printed circuit board disposed on the other of the both opposing sides; and a ground flexible printed circuit board having both opposing sides, wherein one of the both opposing sides of the ground flexible printed circuit board is electrically connected to the display panel, while the other of the both opposing sides of the ground flexible printed circuit board is connected to the second printed circuit board.

According to some embodiment of the present disclosure, the display panel includes: a folding area foldable around a central folding line of the display panel; a first non-folding area located on one side of the folding area; and a second non-folding area located on the other side opposite to one side of the folding area, wherein the folding area is folded such that a display area of the first non-folding area and a display area of the second non-folding area face each other.

According to some embodiment of the present disclosure, the ground flexible printed circuit board includes: a base film; a ground pad disposed at one side end of the base film; an opening spaced apart from the ground pad and extending through the base film; a terminal extending from the base film and located in the opening, wherein the terminal includes a plurality of metal terminal patterns on a rear surface thereof; and a plurality of resistance patterns located on one side of the opening and disposed on the base film.

According to some embodiment of the present disclosure, the base film includes a flexible insulating material.

According to some embodiment of the present disclosure, the terminal is integrated with the base film and extends so as to overlap with the opening.

According to some embodiment of the present disclosure, the terminal includes: a head portion; a middle portion extending from the head portion toward the ground pad and having a width smaller than a width of the head portion; a body portion extending from the middle portion and being bendable; and the plurality of metal terminal patterns disposed on a rear surface of the head portion.

According to some embodiment of the present disclosure, the terminal further includes a cover portion covering an outer surface of a combination of the head portion and the middle portion, wherein the cover portion is relatively stiffer than the base film.

According to some embodiment of the present disclosure, a combination of the plurality of resistance patterns has a resistance value required for impedance matching between one side end of the display panel and the other side end thereof opposite to the one side end.

According to some embodiment of the present disclosure, the plurality of resistance patterns are arranged so as to be spaced apart from each other in a direction toward one side of the opening.

According to some embodiment of the present disclosure, the resistance patterns have different resistance values.

According to some embodiment of the present disclosure, the second printed circuit board further includes a connector structure connected to the ground flexible printed circuit board, wherein the connector structure includes: a housing having an inner space defined therein and constituting an outer appearance of the connector structure; and an actuator connected to the housing and pivotable in an upward or downward direction.

According to some embodiment of the present disclosure, a portion of the ground flexible printed circuit board is received in the inner space of the housing.

According to some embodiment of the present disclosure, the actuator is pivotable in the upward direction or the downward direction to reach a first position to allow the ground flexible printed circuit board and the printed circuit board to contact each other, or to reach a second position to remove the ground flexible printed circuit board and the printed circuit board from each other.

According to some embodiment of the present disclosure, the ground flexible printed circuit board includes: a base film being flexible; a ground pattern disposed on the base film and electrically connected to the printed circuit board to discharge charges accumulated in the display panel to an outside; and a ground pad electrically connected to one side of the display panel.

According to some embodiment of the present disclosure, the ground pattern is attached to the printed circuit board via a conductive double-sided tape or a conductive tape.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above is not restrictive but illustrative in all respects.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a display panel including a display area and a plurality of pixels in the display area, wherein the display panel has a first side and a second side opposite to the first side;
a first printed circuit board disposed on the first side of the display panel;
a second printed circuit board disposed on the second side of the display panel; and
a ground flexible printed circuit board having a first side and a second side opposite to the first side, wherein the first side of the ground flexible printed circuit board is electrically connected to the display panel, and the second side of the ground flexible printed circuit board is connected to the second printed circuit board,
wherein the ground flexible printed circuit board is connected to a ground.

2. The display device of claim 1, wherein the display panel includes:
a folding area configured to fold around a central folding axis of the display panel;
a first non-folding area located on a first side of the folding area; and
a second non-folding area located on a second side of the folding area opposite to the first side of the folding area,
wherein the folding area is configured to fold such that the display area of the first non-folding area and the display area of the second non-folding area face each other.

3. The display device of claim 1, wherein the ground flexible printed circuit board includes:
a base film;
a ground pad disposed at one end of the base film;
an opening spaced apart from the ground pad and extending through the base film;
a terminal extending from the base film and located in the opening, wherein the terminal includes a plurality of metal terminal patterns on a rear surface of the terminal; and
a plurality of resistance patterns located on one side of the opening and disposed on the base film.

4. The display device of claim 3, wherein the base film includes a flexible insulating material.

5. The display device of claim 3, wherein the terminal is integrated with the base film and extends so as to overlap with the opening.

6. The display device of claim 3, wherein the terminal includes:
a head portion;
a middle portion extending from the head portion toward the ground pad and having a width smaller than a width of the head portion;
a body portion extending from the middle portion and being bendable; and
the plurality of metal terminal patterns disposed on a rear surface of the head portion.

7. The display device of claim 6, wherein the terminal further includes a cover portion covering an outer surface of a combination of the head portion and the middle portion, wherein the cover portion is stiffer than the base film.

8. The display device of claim 3, wherein the first side of the display panel is a first end of the display panel and the second side of the display panel is an opposite second end of the display panel, and
wherein a combination of the plurality of resistance patterns has a resistance value for impedance matching between the first side and the second side of the display panel.

9. The display device of claim 8, wherein the plurality of resistance patterns are spaced apart from each other in a direction toward one side of the opening.

10. The display device of claim 9, wherein the resistance patterns have different resistance values.

11. A display device, comprising:
a display panel including a first side and a second side opposite to the first side;
a first printed circuit board disposed on the first side of the display panel;
a second printed circuit board disposed on the second side of the display panel, wherein the second printed circuit board further includes a connector assembly, wherein the connector assembly includes:
a housing having an inner space defined therein; and
an actuator connected to the housing and pivotable in an upward or downward direction; and
a ground flexible printed circuit board coupled to the connector assembly, the ground flexible printed circuit board having a first side and a second side opposite to the first side, wherein the first side of the ground flexible printed circuit board is electrically connected to the display panel, and the second side of the ground flexible printed circuit board is connected to the second printed circuit board by the connector assembly,
wherein the ground flexible printed circuit board is connected to a ground.

12. The display device of claim 11, wherein a portion of the ground flexible printed circuit board is received in the inner space of the housing.

13. The display device of claim 11, wherein the actuator is pivotable in the upward direction or the downward direction to reach a first position to allow the ground flexible printed circuit board and the printed circuit board to contact each other, or to reach a second position to remove the ground flexible printed circuit board and the printed circuit board from each other.

14. The display device of claim 1, wherein the ground flexible printed circuit board includes:
a base film being flexible;
a ground pattern disposed on the base film and electrically connected to the printed circuit board to discharge charges accumulated in the display panel; and
a ground pad electrically connected to one side of the display panel.

15. The display device of claim 14, wherein the ground pattern is attached to the printed circuit board via a conductive double-sided tape or a conductive tape.

16. A display device, comprising:
a display panel including a display area and a plurality of pixels in the display area;
a printed circuit board disposed on the display panel;
a ground flexible printed circuit board having a first side and a second side opposite to the first side, wherein the first side of the ground flexible printed circuit board is electrically connected to the display panel, and the second side of the ground flexible printed circuit board is connected to the printed circuit board,
wherein the ground flexible printed circuit board is connected to a ground.

17. The display device of claim 16, wherein the ground flexible printed circuit board includes:
a base film;
a ground pad disposed on the base film;
an opening extending through the base film;
a terminal extending from the base film and located in the opening; and
a plurality of resistance patterns disposed on the base film.

18. The display device of claim 17, wherein the terminal includes:
a head portion;
a middle portion extending from the head portion toward the ground pad;
a body portion extending from the middle portion and being bendable; and
the plurality of metal terminal patterns disposed on a rear surface of the head portion.

19. The display device of claim 16, wherein the display panel is a foldable display panel configured to fold around a folding axis of the foldable display panel.

20. The display device of claim 16, wherein the printed circuit board further includes a connector assembly, the connector assembly including:
a housing having an inner space defined therein; and
an actuator connected to the housing and pivotable in an upward or downward direction,
wherein a portion of the ground flexible printed circuit board is received in the inner space of the housing.
